(19) United States
(12) Patent Application Publication
(10) Pub. No.: US 2021/0029848 A1
(43) Pub. Date: Jan. 28, 2021

(54) FAN CONTROLS BASED ON LOCATIONS

(71) Applicant: HEWLETT-PACKARD DEVELOPMENT COMPANY, L.P., SPRING, TX (US)

(72) Inventor: TE-YUEH LIN, TAIPEI CITY (TW)

(21) Appl. No.: 16/966,282

(22) PCT Filed: Apr. 13, 2018
(86) PCT No.: PCT/US2018/027525

§ 371 Date: Jul. 30, 2020

(51) Int. Cl. H05K 7/20; G06F 1/20

(52) U.S. Cl. CPC H05K 7/20209; H05K 7/20136; G06F 1/206

(57) ABSTRACT

In example implementations, an apparatus is provided. The apparatus includes a thermal sensor to measure a temperature, a motor, a fan coupled to the motor, a memory, and a processor. The memory stores a thermal policy that includes operation settings of the fan based on the temperature and a quiet indicator. The processor is communicatively coupled to the thermal sensor, the motor, and the memory. The processor controls operation of the motor to operate the fan based on the thermal policy.

### BACKGROUND

Electronic devices can heat up rapidly when operating. Different methods may be employed to help reduce heat in electronic devices. Some solutions may include heat sink designs, ventilation, and/or fans. Fans can be used to help cool electronic devices.

The fan can be electronically controlled and directed towards specific components or areas of the electronic device to help cool the electronic device. For example, in computers the fan may be mounted near a power supply and mother board to help reduce temperatures inside of the computer.

### BRIEF DESCRIPTION OF THE DRAWINGS

FIG. 1 is a block diagram of an example of an apparatus of the present disclosure that changes operation of a fan based on a location or a time;

FIG. 2 is a block diagram of the apparatus of the present disclosure having a thermal policy for a fan based on a location or a time;

FIG. 3 is a block diagram of an example non-transitory computer readable storage medium storing instructions executed by a processor to control a fan based on a location or a time; and

FIG. 4 is a block diagram of an example non-transitory computer readable storage medium storing instructions executed by a processor to modify a thermal policy of an apparatus to control operation of a fan.

### DETAILED DESCRIPTION

Examples described herein provide an apparatus and method for controlling a fan based on a location. As discussed above, electronic devices can use fans to help reduce the temperature of the electronic devices. During operation, fans can generate a large amount of ambient noise from the motor running, squeaking if the fan is off balance, rushing of air moved by the fan, and the like. In certain environments, the fan noise may be a distraction to the user and others near the apparatus with the operating fan.

Examples herein provide an apparatus that can control operation of a fan based on a location. For example, if the location is identified as a “quiet location,” the operation of the fan may be adjusted to reduce fan noise. For example, the fan speed may be adjusted or the fan may be turned off. In one example, the operation of the fan may be controlled by a thermal policy of the apparatus that is modified to include location parameters in addition to thermal parameters for operating the fan.

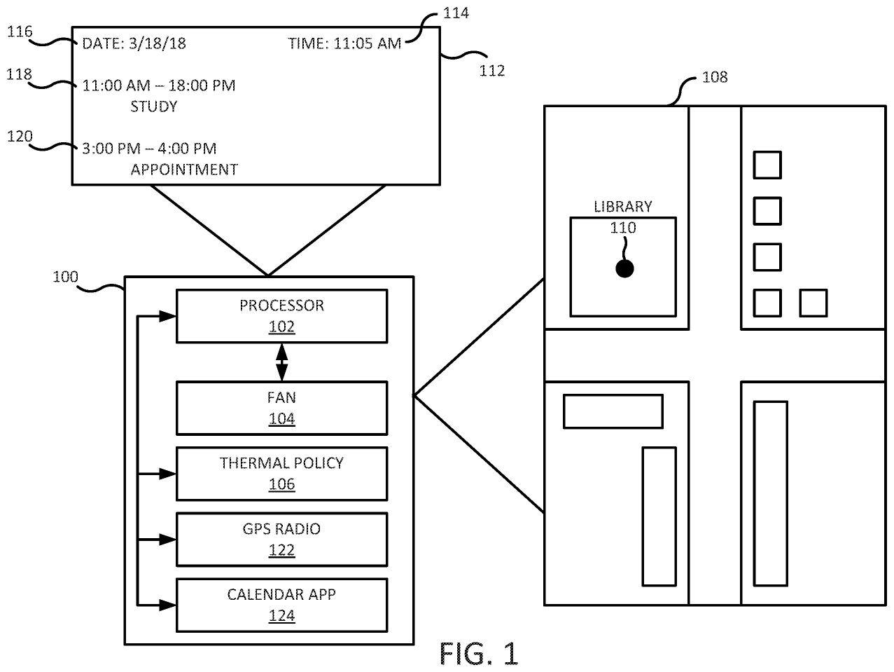

FIG. 1 illustrates a block diagram of an apparatus 100 of the present disclosure that changes operation of a fan 104 based on a location 110 or a current time 114. The apparatus 100 may be laptop computer or any other type of portable computing device.

In one example, the apparatus 100 may include a processor 102, a fan 104, a thermal policy 106, a global positioning system (GPS) radio 122, and a calendar application (also referred to as a calendar app) 124. The processor 102 may be communicatively coupled to the fan 104, the thermal policy 106, the GPS radio 122, and the calendar app 124. It should be noted that the apparatus 100 has been simplified for ease of explanation. For example, the apparatus 100 may include additional components not illustrated in FIG. 1. For example, the apparatus 100 may include input devices (e.g., a touchpad, a touchscreen, a keyboard, and the like), a display, communication interfaces, graphics cards, and the like.

In one example, the thermal policy 106 may store operational settings of the fan 104 based on quiet indicators. The thermal policy 106 may determine how the processor 102 controls operation of the fan 104 (e.g., different speed settings, on or off control, and the like) based on a quiet indicator. The thermal policy 106 may be stored as a table that includes an entry for an operational setting of the fan 104 based on different combinations of different quiet indicators, different temperature thresholds, and the like, as discussed in further details below.

In one example, the quiet indicator may be the location 110 of the apparatus 100 or a current time 114. As discussed above, in certain locations that are identified as quiet locations, or at certain times that are identified as quiet times, the thermal policy 106 may change an expected operation of the fan 104. For example, when an internal temperature of the apparatus 100 exceeds a threshold temperature, the fan 104 may be turned on to cool the apparatus 100. However, the operation of the fan 104 may generate noise that may be distracting.

The thermal policy 106 of the present disclosure may be modified to change operation of the fan 104 even when the internal temperature of the apparatus 100 exceeds the threshold temperature. The thermal policy 106 may change operation of the fan 104 by reducing the speed of the fan 104, stopping the fan 104, and the like.

FIG. 1 illustrates an example where the operation of the fan 104 is changed by the thermal policy 106 based on the location 110 of the apparatus 100. In one example, the GPS radio 122 may collect location information. It should be noted that the GPS radio 122 may be one of many different examples of receiving location information. The processor 102 may receive the location information and compare the location information to quiet locations that are stored in the thermal policy 106.

The quiet locations may be pre-defined by a user. For example, a graphical user interface (GUI) of the apparatus 100 may allow a user to enter, or identify, quiet locations. The quiet locations may be an office location, a home location, a library, government agency locations, and the like.

In one example, the quiet locations may be more granular. For example, the quiet locations may be certain rooms in a large office building. The rooms may be a particular conference room, a shared cubicle location, and the like. The locations of each room may be provided via an access point or local router in the large office building, rather than from the GPS radio 122.

In one example, the quiet locations may be automatically identified based on a comparison of the location 110 of the apparatus to a map database that labels locations on a map 108. For example, the map database may label certain locations such as a library, a school, an office building, and the like. The user may generically identify quiet locations as all libraries, schools, and the like. The processor 102 may then identify a quiet location when the label of the location 110 from a map database matches a quiet location.

In another example, the quiet locations may be automatically learned by the processor 102 over time. For example, the processor 102 may track the locations of the apparatus 100 over a period of time and operation of the fan 104 at those locations. The user may turn off the fan 104 or slow the operational speed of the fan 104 at certain locations. The processor 102 may learn that these certain locations are quiet locations and modify the thermal policy 106 to include those locations as quiet locations.

FIG. 1 also illustrates an example where the operation of the fan 104 is changed by the thermal policy 106 based on the current time 114. The current time 114 may be tracked by an internal clock of the apparatus 100. The current time 114 may be identified as a quiet time period based on information in the calendar application 124.

An example of information 112 contained in the calendar application 124 is illustrated in FIG. 1. The information 112 may include a date 116, a current time 114, and time entries 118 and 120. In one example, the time entries may be identified as quiet times. When the current time 114 falls within a time entry 118 or 120, the thermal policy 106 may change operation of the fan 104, as described above.

In one example, the user may pre-define certain key words as being associated with quiet times. For example, time entries with key words such as “study,” “call,” “meeting,” and the like may be identified as quiet times. Thus, selective time entries (rather than all of the time entries 118 and 120) can be identified as quiet times.

In one example, the thermal policy 106 may be modified to temporarily change operation of the fan 104 based on the location 110 or the current time 114. For example, changing the operation of the fan 104 for too long a period of time may cause permanent damage to the processor 102 or other electronic components within the apparatus 100. Thus, the change of the operation of the fan 104 may be temporary for a pre-defined duration (e.g., 5 minutes, 30 minutes, 1 hour, and the like) while at the location 110 or when the current time 114 is within a quiet time. The thermal policy 106 may include a respective pre-defined duration for each operation setting stored in the thermal policy 106.

In one example, the processor 102 may cause a notification to be displayed to the user when the temporary change to the operation of the fan 104 is about to expire. In one example, the notification can be provided after a pre-defined amount of time (e.g., 30 minutes, 1 hour, and the like) has elapsed while the fan is temporarily operating based on the thermal policy 106. The notification may provide the user with an option to maintain the change in the operation of the fan 104 while at the location 110, or while the current time 114 is within the quiet time. The notification may include a warning that further extending the change in operation of the fan 104 may cause overheating of the apparatus 100 and potentially damage internal components.

In one example, the notification may be displayed when a critical temperature threshold is exceeded. For example, the critical temperature may be a predefined temperature that may override the thermal policy 106. For example, the critical temperature may be a temperature that is known to damage electrical components within the apparatus 100. The notification may be displayed via the GUI of the apparatus 100 and let the user know that the critical temperature has been exceeded and that the thermal policy 106 is being overridden. In other words, the fan 104 may be turned on even when the apparatus 100 is in a quiet location or the current time is within a quiet time. The notification may provide a warning to the user to allow the user to temporarily move from the location 110 or move the quiet time to another time period in the calendar application 124.

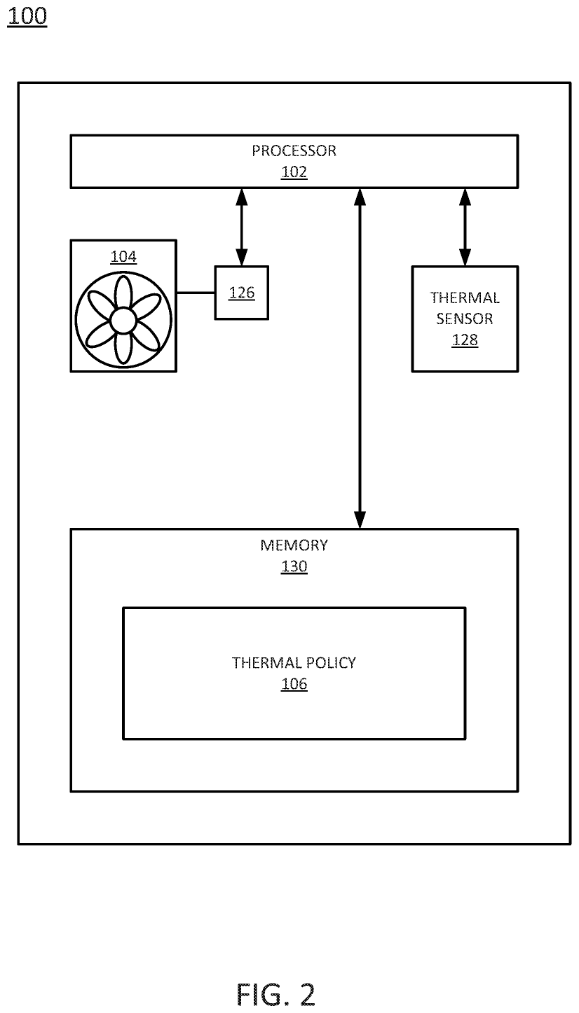

FIG. 2 illustrates a block diagram of the apparatus 100 having the thermal policy 106. The apparatus 100 may include the processor 102, the fan 104, and the thermal policy 106, as illustrated in FIG. 1. The processor 102 may be communicatively coupled to a motor 126, a thermal sensor 128, and a memory 130.

In one example, the thermal policy 106 may be stored in the memory 130. The memory 130 may be a non-transitory computer readable storage medium. The memory 130 may store other information such as the temperature threshold or the critical temperature threshold, described above. The memory 130 may also store other information such as the quiet locations that are labeled or identified, the map 108, the calendar application 124, the key words that identify quiet times, and the like.

In one example, the fan 104 may be coupled to a motor 126. The processor 102 may control operation of the motor 126 to control the fan 104. For example, increasing power to the motor 126 may increase the speed of the fan 104 to increase cooling, but at a cost of more noise. Decreasing power to the motor 126 may decrease the speed of the fan 104 to lower the amount of fan noise. Stopping the motor 126 may stop operation of the fan 104.

In one example, the processor 102 may control operation of the motor 126 based on the thermal policy 106. The thermal policy 106 may store different operational settings of the fan 104 based on a combination of different temperatures and different quiet indicators. A quiet indicator may include the location 110 of the apparatus 100 or the current time 114. For example, the fan may be turned off when in a quiet location. However, when the internal temperature reaches a first temperature threshold, the fan 104 may be operated at a low speed setting. When the internal temperature reaches a second temperature threshold, a notification may be presented to the user indicating that the fan 104 may be turned on to a high speed to cool the apparatus 100.

In another example, the fan 104 may be turned off during a quiet time. When the internal temperature reaches a first temperature threshold, the fan 104 may be operated at a low speed setting. The first temperature threshold associated with the quiet location may be different than the first temperature threshold associated with the quiet time. For example, the first temperature threshold associated with the quiet location may be higher than the first temperature threshold associated with the quiet time to ensure that the fan 104 stays off longer.

In one example, the temperature may be measured by the thermal sensor 128. The thermal sensor 128 may be any type of temperature measuring device. For example, the thermal sensor 128 may be a thermistor, a thermocouple, a resistance thermometer, and the like.

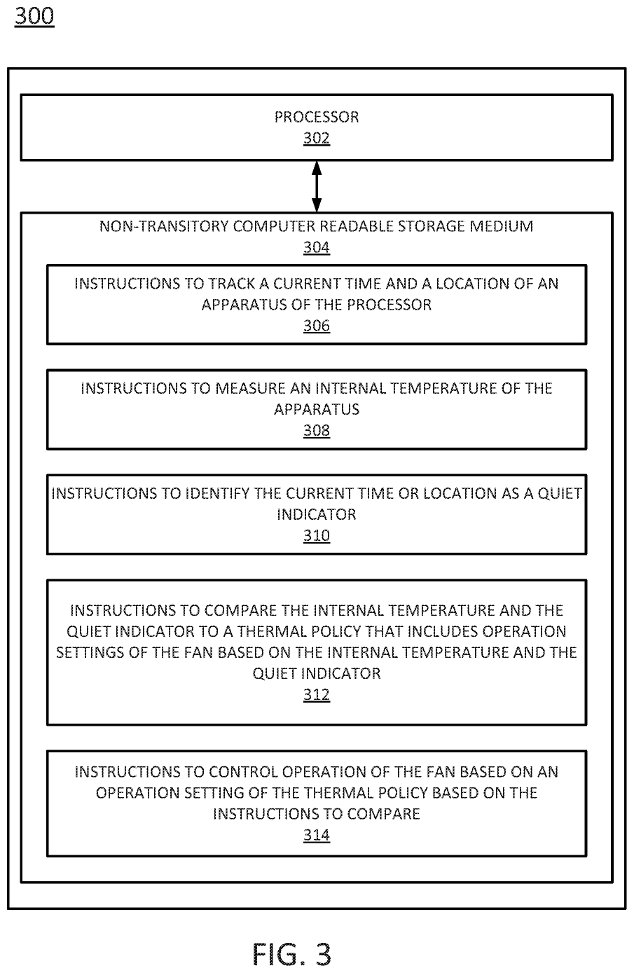

FIG. 3 illustrates an example of an apparatus 300. In one example, the apparatus 300 may be the apparatus 100. In one example, the apparatus 300 may include a processor 302 and a non-transitory computer readable storage medium 304. The non-transitory computer readable storage medium 404 may include instructions 306, 308, 310, 312, and 314 that, when executed by the processor 302, cause the processor 302 to perform various functions to control a fan based on a location or a time.

In one example, the instructions 306 may include instructions to track a current time and a location of an apparatus of the processor. For example, the location of the apparatus may be tracked using a GPS radio of the apparatus. In another example, the location of the apparatus may be tracked based on information received from an access point in communication with a wireless radio (e.g., a Wi-Fi antenna or any other type of wireless communication interface) of the apparatus. The current time may be tracked using an internal clock of the apparatus.

The instructions 308 may include instructions to measure an internal temperature of the apparatus. For example, the internal temperature may be continuously measured by a thermal sensor and monitored by the processor of the apparatus.

The instructions 310 may include instructions to identify the current time or the location as a quiet indicator. For example, the quiet indicator may be the current time being a quiet time or the location being a quiet location. The quiet time or the quiet location may be identified, as discussed above. The current time may be compared to quiet time hours to determine if the current time falls within the quiet time hours, or the location of the apparatus may be compared to quiet locations to determine if the location of the apparatus is in a quiet location.

The instructions 312 may include instructions to compare the internal temperature and the quiet indicator to a thermal policy that includes operation settings of the fan based on the internal temperature and the quiet indicator. The operation settings of the thermal policy may change operation of the fan based on the quiet indicator (e.g., the quiet time or the quiet location) and the internal temperature. For example, the thermal policy may set different temperature thresholds (e.g., temperature thresholds that may be higher in a quiet location or during a quiet time than temperature thresholds in non-quiet locations or non-quiet times) for the different quiet indicators. The currently identified quiet location or quiet time and the current temperature of the apparatus may be found in the thermal policy to determine the operational setting of the fan.

The instructions 314 may include instructions to control operation of the fan based on an operation setting of the thermal policy based on the instructions to compare. For example, the fan may be slowed down, the fan may be stopped, and the like. The operation of the fan based on the thermal policy may be temporary or may be overridden if the internal temperature exceeds a critical temperature threshold, as described above.

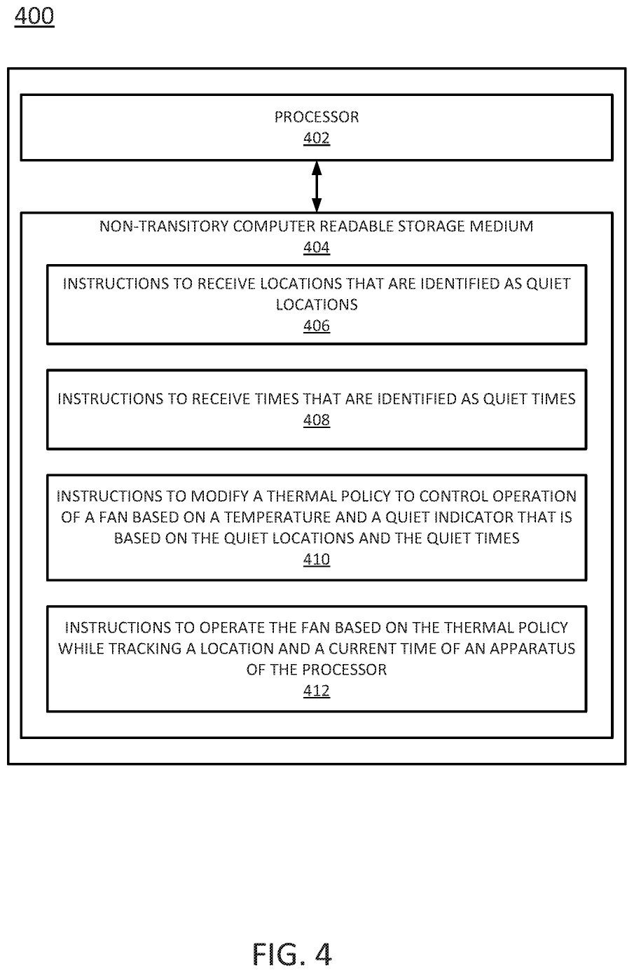

FIG. 4 illustrates an example of an apparatus 400. In one example, the apparatus 400 may be the apparatus 100. In one example, the apparatus 400 may include a processor 402 and a non-transitory computer readable storage medium 404. The non-transitory computer readable storage medium 404 may include instructions 406, 408, 410, and 412 that, when executed by the processor 402, cause the processor 402 to perform various functions to modify a thermal policy of an apparatus to control operation of a fan.

In one example, the instructions 406 may include instructions to receive locations that are identified as quiet locations. The quiet locations may be provided by a user via a GUI, may be identified based on labels of locations on a map from a map database, or learned based on user operation of the fan at tracked locations.

The instructions 408 may include instructions to receive times that are identified as quiet times. The quiet times may be provided via a calendar application that includes time periods with appointments. In one example, key words may be used to identify appointments that are associated with a quiet time, as described above.

The instructions 410 may include instructions to modify a thermal policy to control operation of a fan based on a temperature and a quiet indicator that is based on the quiet locations and the quiet times. For example, the thermal policy may be modified to include the quiet locations that are identified and the quiet times that are identified. Different temperature thresholds may be set for each one of the quiet locations and each one of the quiet times. The different temperature thresholds may be the same, or may be different, for the different quiet locations and the different quiet times. An operation setting of the fan may be associated with each one of the different temperature thresholds.

For example, during normal operation of the fan, the fan may be turned on to a maximum speed when the temperature exceeds a normal operating temperature threshold (e.g., 80 Fahrenheit (° F.)). Thus, in locations that are not identified as a quiet location, the fan may operate at maximum speeds when the temperature exceeds 80° F.

The thermal policy may be modified to such that at a first quiet location, a first temperature threshold (e.g., 100 degrees Fahrenheit (° F.)) may be set and a second temperature threshold (e.g., 150° F.) may be set. The operational setting of the fan may be in an off state when the internal temperature is below the first threshold. The operational setting of the fan maybe in a low state when the first temperature threshold is exceeded. The operation setting of the fan may be a maximum speed when the second temperature setting is exceeded.

Thus, in a quiet location the fan may not turn on even though the internal temperature may exceed the normal operating temperature threshold of 80° F. To help minimize noise, the fan may operate at a low setting to minimize fan noise when the first temperature threshold is exceeded and the apparatus is in the quiet location. However, at some point the internal temperature may rise to a level that can damage the electrical components inside of the apparatus. As a result, the fan may operate at a maximum speed when the second temperature threshold is exceeded. In one example, a notification may be displayed to the user to allow the user to leave the quiet location if the fan noise may be disturbing to others in the quiet location, as described above.

The instructions 412 may include instructions to operate the fan based on the thermal policy while tracking a location and a current time of an apparatus of the processor. Thus, the apparatus may operate the fan in accordance with the modified thermal policy. If the apparatus leaves the quiet location or the current time is no longer a quiet time, the apparatus may operate the fan in accordance with a normal operation, as described above.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. An apparatus, comprising:
a thermal sensor to measure a temperature;
a motor;
a fan coupled to the motor;
a memory to store a thermal policy that includes operation settings of the fan based on the temperature and a quiet indicator; and
a processor communicatively coupled to the thermal sensor, the motor, and the memory, wherein the processor to control operation of the motor to operate the fan based on the thermal policy.

2. The apparatus of claim 1, further comprising:
a global positioning system (GPS) radio to detect a location of the apparatus.

3. The apparatus of claim 2, wherein the quiet indicator comprises a quiet location based on a location detected by the GPS radio.

4. The apparatus of claim 3, wherein the quiet location is defined by a user.

5. The apparatus of claim 3, wherein the quiet location is identified by comparison of the location to a map database that labels locations on the map.

6. The apparatus of claim 1, wherein the current time is identified as a quiet time period based on calendar information.

7. The apparatus of claim 1, wherein the operation settings comprise different fan speed settings based on a combination of different temperatures and different quiet indicators.

8. A non-transitory computer readable storage medium encoded with instructions executable by a processor, the non-transitory computer-readable storage medium comprising:
instructions to track a current time and a location of an apparatus of the processor;
instructions to measure an internal temperature of the apparatus;
instructions to identify the current time or the location as a quiet indicator;
instructions to compare the internal temperature and the quiet indicator to a thermal policy that includes operation settings of the fan based on the internal temperature and the quiet indicator; and
instructions to control operation of the fan based on an operation setting of the thermal policy based on the instructions to compare.

9. The non-transitory computer readable storage medium of claim 8, where the location is tracked by information from an access point in communication with a wireless radio of the apparatus or a global position system (GPS) radio of the apparatus.

10. The non-transitory computer readable storage medium of claim 8, wherein the thermal policy comprises a respective pre-defined duration for each one of the operation settings.

11. The non-transitory computer readable storage medium of claim 8, wherein the thermal policy has a different operation setting for the fan based on the internal temperature than an operation setting for the fan based on the internal temperature and the quiet indicator.

12. A non-transitory computer readable storage medium encoded with instructions executable by a processor, the non-transitory computer-readable storage medium comprising:
instructions to receive locations that are identified as quiet locations;
instructions to receive times that are identified as quiet times;
instructions to modify a thermal policy to control operation of a fan based on a temperature and a quiet indicator that is based on the quiet locations and the quiet times; and
instructions to operate the fan based on the thermal policy while tracking a location and a current time of an apparatus of the processor.

13. The non-transitory computer readable storage medium of claim 12, wherein the instructions to operate the fan comprise reducing a speed of the fan.

14. The non-transitory computer readable storage medium of claim 12, wherein the instructions to operate the fan comprise stopping operation of the fan.

15. The non-transitory computer readable storage medium of claim 12, further comprising:
instructions to display a notification to provide an option to continue operation of the fan based on the thermal policy after a pre-defined amount of time.
